(19) United States
(12) Patent Application Publication
(10) Pub. No.: US 2025/0212336 A1
(43) Pub. Date: Jun. 26, 2025

(54) PRINTED CIRCUIT BOARD

(71) Applicant: SAMSUNG ELECTRO-MECHANICS CO., LTD., Suwon-si (KR)

(72) Inventors: Ki Ran PARK, Suwon-si (KR); Kyeong Yub JUNG, Suwon-si (KR); Myong Keun JUNG, Suwon-si (KR); Jin Oh PARK, Suwon-si (KR); Tae Yang KIM, Suwon-si (KR)

(73) Assignee: SAMSUNG ELECTRO-MECHANICS CO., LTD., Suwon-si (KR)

(21) Appl. No.: 18/970,530

(22) Filed: Dec. 5, 2024

(30) Foreign Application Priority Data
Dec. 21, 2023 (KR) 10-2023-0188535

(51) Int. Cl. H05K 1/18; H05K 1/11

(52) U.S. Cl. CPC H05K 1/185; H05K 1/115; H05K 2201/029; H05K 2201/09481; H05K 2201/09527; H05K 2201/096; H05K 2201/09618; H05K 2201/09727; H05K 2201/09827; H05K 2201/099; H05K 2201/10318

(57) ABSTRACT

A printed circuit board includes an interconnection portion including one or more insulating layers, one or more interconnection layers, and one or more via layers and having a cavity penetrating through at least a portion of the one or more insulating layers, an electronic component disposed in the cavity, a first insulating material disposed in at least a portion of the cavity and burying at least a portion of the electronic component, a second insulating material disposed on the first insulating material, and a micro-via penetrating through at least a portion of the second insulating material and connected to the electronic component. The micro-via has a width smaller than at least one via among the one or more via layers.

### CROSS-REFERENCE TO RELATED APPLICATION(S)

This application claims benefit of priority to Korean Patent Application No. 10-2023-0188535 filed on Dec. 21, 2023 in the Korean Intellectual Property Office, the disclosure of which is incorporated herein by reference in its entirety.

### TECHNICAL FIELD

The present disclosure relates to a printed circuit board.

Recently, due to the recent development of artificial intelligence (AI) technology, etc., multi-chip packages including memory chips, such as high bandwidth memory (HBM) and processor chips, such as a central processing unit (CPU), a graphics processing unit (GPU), an application specific integrated circuit (ASIC), and field programmable gate array (FPGA) for processing exponentially increasing data have been used. In particular, the number of CPU and GPU cores in server products has increased rapidly, and it is necessary to respond to a finer chip metal post pitch. In particular, research has been conducted to form the pads of a substrate finer to connect chips to the substrate and to increase the yield thereof, while improving the reliability of the connection between the chips and the substrate.

### SUMMARY

An aspect of the present disclosure is to provide a printed circuit board capable of implementing a metal post having a fine pitch in the printed circuit board for mounting electronic components and semiconductor chips, etc.

Another aspect of the present disclosure is to provide a printed circuit board having improved reliability against warpage.

According to an aspect of the present disclosure, a printed circuit board includes: an interconnection portion including one or more insulating layers, one or more interconnection layers, and one or more via layers and having a cavity penetrating through at least a portion of the one or more insulating layers; an electronic component disposed in the cavity; a first insulating material disposed in at least a portion of the cavity and burying at least a portion of the electronic component; a second insulating material disposed on the first insulating material; and a micro-via penetrating through at least a portion of the second insulating material and connected to the electronic component. The micro-via has a width smaller than at least one of the one or more via layers.

According to another aspect of the present disclosure, a printed circuit board includes: an interconnection portion including one or more insulating layers and one or more interconnection layers and having a cavity penetrating through at least a portion of the one or more insulating layers; a first insulating material filling at least a portion of the cavity; and a second insulating material disposed on the first insulating material and including a reinforcing material, wherein an uppermost interconnection layer among the one or more interconnection layers includes a first pad, and an upper surface of the first pad is located within the second insulating material.

### BRIEF DESCRIPTION OF DRAWINGS

This and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating a printed circuit board according to an example;

FIG. 4 is an enlarged view of portion A of FIG. 3; and

FIGS. 5 to 12 are cross-sectional views schematically illustrating a method for manufacturing a printed circuit board according to an example.

### DETAILED DESCRIPTION

Hereinafter, the present disclosure is described with reference to the accompanying drawings. In the drawings, the shapes and sizes of components may be exaggerated or reduced for a clearer description.

### Electronics

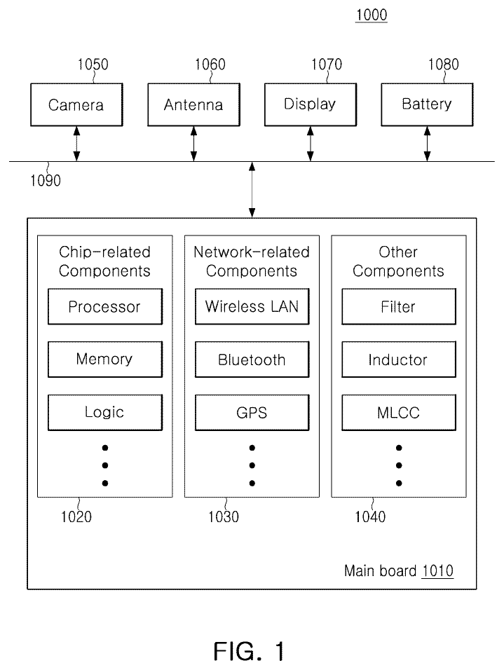

FIG. 1 is a block diagram schematically illustrating an example of an electronic device system.

Referring to FIG. 1, an electronic device 1000 accommodates a main board 1010. A chip-related component 1020, a network-related component 1030, and other components 1040 are physically and/or electrically connected to the main board 1010. These components are combined with other electronic components to be described below to form various signal lines 1090.

The chip-related component 1020 includes memory chips, such as volatile memories (e.g., DRAM), non-volatile memory (e.g., ROM), and flash memories; application processor chips, such as central processors (e.g., CPUs), graphics processors (e.g., GPUS), signal digital processors, encryption processors, microprocessors, and microcontrollers; logic chips, such as analog-to-digital converters (ADCs), and application-specific integrated circuits (ASICs), but the present disclosure is not limited thereto and may include other types of chip-related electronic components as well. In addition, these chip-related components 1020 may be combined with each other. The chip-related component 1020 may be in the form of a package including the aforementioned chip or electronic component.

The network related component 1030 may include Wi-Fi (IEEE 802.11 family, etc.), WiMAX (IEEE 802.16 family, etc.), IEEE 802.20, long term evolution (LTE), Ev-DO, HSPA+, HSDPA+, HSUPA+, EDGE, GSM, GPS, GPRS, CDMA, TDMA, DECT, Bluetooth, 3G, 4G, 5G, and any other wireless and wired protocols designated thereafter, but is not limited to and may include any of other wireless or wired standards or protocols. In addition, the network-related component 1030 and the chip-related component 1020 may be combined with each other.

The other components 1040 include high-frequency inductors, ferrite inductors, power inductors, ferrite beads, low temperature co-firing ceramics (LTCCs), electro-magnetic interference (EMI) filters, multilayer ceramic condensers (MLCCs), and the like. However, the other components 1040 are not limited thereto and may include passive elements in the form of chip components used for various other purposes. In addition, the other components 1040 may be combined with the chip-related component 1020 and/or the network-related component 1030.

Depending on the type of electronic device 1000, the electronic device 1000 may include other electronic components that may or may not be physically and/or electrically connected to the main board 1010. The other electronic components may include, for example, a camera 1050, an antenna 1060, a display 1070, and a battery 1080. However, the electronic components are not limited thereto and may include audio codecs, video codecs, power amplifiers, compasses, accelerometers, gyroscopes, speakers, mass storage devices (e.g., hard disk drives), compact disks (CDs), digital versatile disks (DVDs), etc. In addition, other electronic components used for various purposes may be included depending on the type of the electronic device 1000.

The electronic device 1000 may include smartphones, personal digital assistants (PDAs), digital video cameras, digital still cameras, network systems, computers, monitors, tablets, laptops, netbooks, televisions, video game machines, smart watches, automotives, and the like. However, the electronic device 1000 is not limited thereto, and may be any other electronic device that processes data in addition thereto.

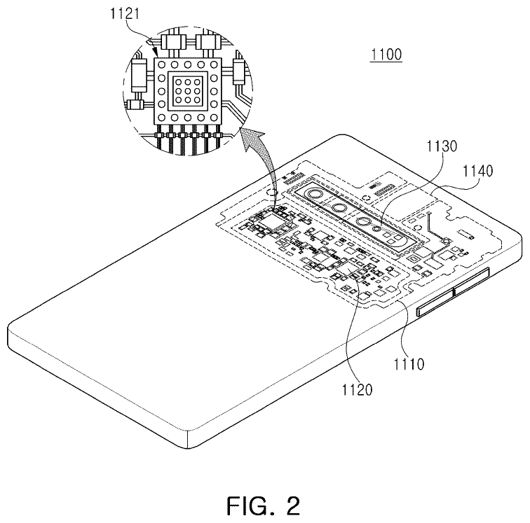

FIG. 2 is a perspective view schematically illustrating an example of an electronic device.

Referring to FIG. 2, the electronic device may be, for example, a smartphone 1100. A motherboard 1110 is accommodated inside the smartphone 1100, and various components 1120 are physically and/or electrically connected to the motherboard 1110. In addition, other components that may or may not be physically and/or electrically connected to the motherboard 1110, such as a camera module 1130 and/or a speaker 1140, are accommodated in the smartphone 1100. Some of the components 1120 may be the aforementioned chip-related components, for example, a component package 1121, but the present disclosure is not limited thereto. The component package 1121 may be in the form of a printed circuit board (PCB) on which electronic components including active components and/or passive components are surface-mounted. Alternatively, the component package 1121 may be in the form of a PCB in which active components and/or passive components are embedded. Meanwhile, the electronic device is not necessarily limited to the smartphone 1100, and may be other electronic devices as described above.

### Printed Circuit Board

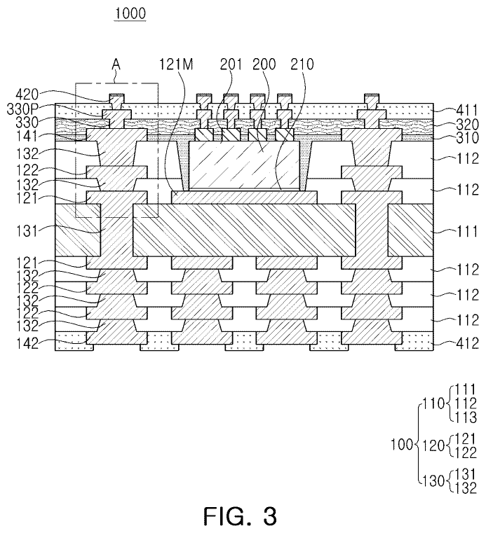

FIG. 3 is a cross-sectional view schematically illustrating a printed circuit board according to an example.

Referring to FIG. 3, the printed circuit board according to an example may include an interconnection portion 100, a first insulating material 310, a second insulating material 320 and may further include an electronic component 200, a micro-via 330, a solder resist layer 411, and a metal post 420.

The interconnection portion 100 may include one or more insulating layers 110, one or more interconnection layers 120 respectively arranged on or within the one or more insulating layers, and one or more via layers 130 penetrating through the one or more insulating layers to connect the one or more interconnection layers, and may have a cavity penetrating through at least a portion of the one or more insulating layers.

The electronic component 200 may be disposed within the cavity. A connection pad 201 may be disposed on an upper surface of the electronic component 200.

The first insulating material 310 may fill at least a portion of the cavity and may bury at least a portion of the electronic component 200. The first insulating material 310 may be formed of a material including an insulating material but not including a fiber reinforcing material, such as glass cloth, for example, Ajinomoto build-up film (ABF). ABF may be provided in the form of resin coated copper (RCC), but the present disclosure is not limited thereto. If necessary, a photosensitive insulating material, such as photo imagable dielectric (PID) may be used.

The second insulating material 320 is disposed on the first insulating material 310 and may include a reinforcing material. Specifically, the second insulating material 320 may include a fiber reinforcing material, such as glass cloth, and may be, for example, a prepreg. The second insulating material 320 including a fiber reinforcing material, such as glass cloth, may further strengthen rigidity of the printed circuit board 1000 and improve the reliability of the printed circuit board against warpage.

In the printed circuit board 1000 according to the present exemplary embodiment, the first and second insulating materials 310 and 320 are disposed on the upper 200. The second surface of the electronic component insulating material 320 may be a prepreg including a fiber reinforcing material, such as glass cloth, and a micro-via hole may be formed by punching using a mold before the second insulating material 320 is stacked. However, a size of the micro-via hole may decrease due to flow of a resin during a thermal compression process of the prepreg. Therefore, the electronic component 200 is embedded in the first insulating material 310 before the second insulating material 320 is stacked, thereby minimizing the volume that has to be filled with the second insulating material 320.

The uppermost interconnection layer among the one or more interconnection layers 120 may include a first pad 141. The first pad 141 may be disposed on the uppermost insulating layer 112 among one or more insulating layers 110. An upper surface of the first pad 141 may be located within the second insulating material 320. A side surface of the first pad 141 may be in contact with the first insulating material 310 and the second insulating material 320. A boundary surface between the first insulating material 310 and the second insulating material 320 may be located between the upper surface and a lower surface of the first pad 141. This is because, as is described below, after the first insulating material 310 is formed, a portion of the first insulating material 310 may be etched through an etching process.

An upper surface of the connection pad 201 of the electronic component 200 may be located within the second insulating material 320. A side surface of the connection pad 201 may be in contact with the first insulating material 310 and the second insulating material 320. Similarly, the boundary surface of the first insulating material 310 and the second insulating material 320 may be located between an upper surface and a lower surface of the connection pad 201.

When a cross-section is observed using a measuring device, such as a scanning electron microscope (SEM), the boundary surface of the first insulating material 310 and the second insulating material 320 may be identified by distinguishing the presence or absence of the reinforcing material.

The micro-via 330 may penetrate through at least a portion of the second insulating material 320. The micro-via 330 may have a with (e.g., diameter) smaller than at least one via among the one or more via layers 130. Specifically, the micro-via 330 may have a width (e.g., diameter) d₃₃₀ smaller than a width (e.g., diameter) d₁₃₁ of the first via 131 and/or the width (e.g., diameter) d₁₃₂ of the second via 132 described below. In addition, the micro-via 330 may have a width (e.g., diameter) smaller than a width (e.g., diameter) d₁₄₁ of the first pad 141.

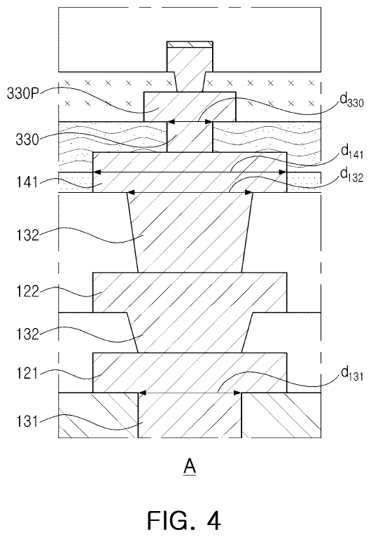

FIG. 4 is an enlarged view of portion A of FIG. 3.

As illustrated in FIG. 4, when a side surface of the via is tapered, a width (e.g., diameter) of one end portion of the via may be larger than a width (e.g., diameter) of the other end thereof. In this case, as illustrated in FIG. 4, the width (e.g., diameter) of the one end portion, which is relatively large, may be measured and used as the width (e.g., diameter). However, the present disclosure is not limited thereto, and the width (e.g., diameter) of the other end portion may be measured according to convenience. The width (e.g., diameter) of the via may be measured multiple times, and an arithmetic mean of values measured multiple times may be used as the width (e.g., diameter).

The micro-via 330 may be spaced apart from one or more of the insulating layers 110. The micro-via 330 may be spaced apart from the first insulating material 310. As described above, after the first insulating material 310 is formed, a portion of the first insulating material 310 may be etched through an etching process.

The solder resist layer 411 may be disposed on an upper surface of the second insulating material 320.

The metal post 420 may be disposed on the micro-via 330 and may penetrate through at least a portion of the solder resist layer 411.

The one or more insulating layers 110 may include a first insulating layer 111 which is a core layer and a second insulating layer 112 which is a build-up insulating layer. The insulating layer 110 may include an insulating material. The insulating material may include a thermosetting resin, such as an epoxy resin, a thermoplastic resin, such as a polyimide, or a material including an inorganic filler, an organic filler, and/or glass fiber (glass cloth, and/or glass fabric) together with the resin. The insulating material may be a photosensitive material and/or a non-photosensitive material. For example, the insulating material of the insulating layer 110 may be, but is not limited to, an insulating material of ABF, but without being limited thereto, the insulating material of the insulating layer 110 may include prepreg (PPG), resin coated copper (RCC), photo imagable dielectric (PID), FR-4, bismaleimide triazine (BT), etc. However, without being limited thereto, other materials with excellent rigidity, such as glass materials, may be used if necessary.

The cavity may penetrate through at least a portion of the second insulating layer 112. The cavity may not penetrate through the first insulating layer 111, which is the core layer. That is, the cavity according to the present exemplary embodiment may be a blind cavity.

One or more interconnection layers 120 may include a first interconnection layer 121 disposed on the first insulating layer 111 and a second interconnection layer 122 as a build-up interconnection layer disposed on or within the second insulating layer 112. Specifically, the interconnection layer disposed on or within the uppermost insulating layer among the second insulating layers 112 may be referred to as a first pad 141.

The interconnection layer 120 may include a metal material. As the metal material, copper (Cu), aluminum (Al), silver (Ag), tin (Sn), gold (Au), lead (Pb), titanium (Ti), or alloys thereof may be used. The metal material may preferably include copper (Cu), but the present disclosure is not limited thereto, and the first interconnection layer 121 and the second interconnection layer 122 may include different metal materials. The interconnection layer 120 may perform various functions depending on the design. For example, the interconnection layer 120 may include a signal pattern, a power pattern, a ground pattern, etc., but without being limited thereto, and the interconnection layer 120 may function as a pad for mounting electronic components and chips or may function as a stopper for forming a cavity. These patterns may each have various shapes, such as a line, a plane, and a pad. The interconnection layer 120 may have different pitches depending on the function thereof. When the interconnection layer 120 requires a high-density fine pitch for connection with a connection structure or a semiconductor chip, a gap between the interconnection layers 120 may be narrowed, and when performing signal connections, the gap between the interconnection layers 120 may be widened.

The interconnection layer 120 may be formed by any one of a semi additive e process (SAP), a modified semi additive process (MSAP), tenting (TT), or Subtractive method, but the present disclosure is not limited thereto. The interconnection layer 120 may include an electroless plating layer (or chemical copper) as a seed layer and an electrolytic plating layer (or electrolytic copper) as a plating layer, but the present disclosure is not limited thereto. Instead of chemical copper as the electroless plating layer, a sputtering layer may be formed. If necessary, the interconnection layer 120 may further include a copper foil.

The one or more via layers 130 may penetrate through one or more insulating layers 110 to connect the one or more interconnection layers 120. The one or more via layers 130 may include a first via layer as a via penetrating through the first insulating layer 111 and a second via layer 132 as a build-up via layer penetrating through at least a portion of the second insulating layer 112.

The first via layer 131 may include a metal layer formed on a wall surface of a through-hole penetrating through the first insulating layer 111 and a plug filling the metal layer. The metal layer may include copper (Cu), aluminum (Al), silver (Ag), tin (Sn), gold (Au), nickel (Ni), lead (Pb), titanium (Ti), or alloys thereof, and may preferably include copper (Cu), but the present disclosure is not limited thereto. The plug may include ink of an insulating material. The metal layer may include an electroless plating layer (or chemical copper) and an electrolytic plating layer (or electrolytic copper), but the present disclosure is not limited thereto. Instead of the electroless plating layer, a sputtering layer may be formed, and both may be included. The first via layer 131 may perform various functions depending on the design. For example, the first via layer 131 may include a ground via, a power via, a signal via, etc.

The second via layer 132 may include a micro-via. The micro-via may be a filled via filling a via hole or a conformal via disposed along a wall surface of the via hole. The micro-via may be disposed in a stacked type and/or a staggered type. Each of the second via layers 132 may include a metal, and the metal may include copper (Cu), aluminum (Al), silver (Ag), tin (Sn), gold (Au), nickel (Ni), lead (Pb), titanium (Ti), or alloys thereof, and may preferably include copper (Cu), but the present disclosure is not limited thereto. The second via layer 132 may include an electroless plating layer (or chemical copper) and an electrolytic plating layer (or electrolytic copper), but the present disclosure is not limited thereto. Instead of the electroless plating layer, a sputtering layer may be formed, and both may be included. The second via layer 132 may perform various functions depending on the design of the corresponding layer. For example, the second via layer may include a ground via, a power via, a signal via, etc.

According to an example, an interconnection layer disposed on the uppermost portion among the one or more interconnection layers 120 of the printed circuit board may include a first pad 141. The first pad 141 may be disposed on or within the insulating layer disposed on the uppermost portion among the second insulating layers 112. As described above, the interconnection layer disposed on the uppermost insulating layer among the second insulating layers 112 may be referred to as the first pad 141. In FIG. 3, the first pad 141 is illustrated as being located on the second insulating layer 112 and protruding upwardly from the second insulating layer 112, but without being limited thereto, the first pad 141 may also be embedded in the second insulating layer 112. The first pad 141 may be connected to at least a portion of the second interconnection layer 122 through one via layer 130 among the second via layers 132.

The first pad 141 may include a metal material, and the metal material may include copper (Cu), aluminum (Al), silver (Ag), tin (Sn), gold (Au), nickel (Ni), lead (Pb), titanium (Ti), and/or alloys thereof, and may preferably include copper (Cu), but the present disclosure is not limited thereto. The first pad 141 may be disposed on top of the printed circuit board, may be a region for mounting electronic components and chips, and may be connected to a circuit pattern to perform signal connection with other pads. However, the present disclosure is not limited thereto, and the micro-via 330 may be formed above the first pad 141. The first pad 141 may perform various functions depending on the design. For example, the first pad 141 may include a ground pad, a power pad, a signal pad, and the like. Here, the signal pad may include a pad for electrical connection of various signals other than ground, power, etc., for example, a data signal. In a case in which the first pad 141 requires a high-density fine pitch for mounting semiconductor chips, etc., a gap between the first pads 141 may be narrowed, and in a case in which electronic components are mounted, the gap between the first pads 141 may be widened.

The printed circuit board according to an example may include a second pad 142 below the interconnection portion 100. The second pad 142 may be disposed on or within the insulating layer that is disposed at the lowest portion among the second insulating layers 112. In FIG. 3, the second pad 142 is illustrated as being disposed on the second insulating layer 112 and protruding from a lower portion of the second insulating layer 112, but it is not limited thereto, and the printed circuit board may have a coreless structure in which the second pad 142 is embedded on a lower side of the second insulating layer 112. The second pad 142 may be connected to at least a portion of the second interconnection layer 122 through one of the second via layers 132. The second pad 142 may include a metal material, and the metal material may include copper (Cu), aluminum (Al), silver (Ag), tin (Sn), gold (Au), nickel (Ni), lead (Pb), titanium (Ti), and/or alloys thereof, and may preferably include copper (Cu), but the present disclosure is not limited thereto.

The second pad 142 may be disposed at the bottom of the printed circuit board and may function as a connection pad so that a lower surface of the printed circuit board may be connected to another component, such as a main board. However, the present disclosure is not limited thereto, and the second pad 142 may also function to connect to a component having a fine pitch, such as a semiconductor chip, and the pitch may be designed variously depending on the function. The second pad 142 may each perform various functions depending on the design. For example, the second pad 142 may include a ground pad, a power pad, a signal pad, etc. Here, the signal pad may include a pad for electrical connection of various signals, such as data signals, excluding ground and power.

The first pad 141 and the second pad 142 may be formed by any one of the SAP, MSAP, TT, or Subtractive method, but are not limited thereto, and may be formed using a method that may be used by a person skilled in the art.

The micro-via 330 may be connected to the electronic component 200 through at least a portion of the second insulating material 320. The micro-via 330 may be disposed on top of the printed circuit board, may be a region for mounting electronic components and chips, and may be connected to a circuit pattern to perform signal connection with other pads. The micro-vias 330 may perform various functions depending on the design. For example, the micro-vias 330 may include a ground pad, a power pad, a signal pad, etc. Here, the signal pad may include a pad for electrical connections of various signals, such as data signals, excluding ground and power. When the micro-vias 330 require a high-density micro pitch for mounting semiconductor chips, etc., a gap between the micro-vias 330 may be narrowed, and when mounting electronic components, the gap between the micro-vias 330 may be widened.

As described above, the micro-vias 330 may have a smaller width (e.g., diameter) than at least one via among the one or more via layers 130. The micro-via 330 may be formed by forming a micro-via hole by punching the second insulating material 320 using a mold before the second insulating material 320 is stacked, and may be formed by a method, such as SAP, MSAP, TT, or Subtractive. However, without being limited thereto, the micro-via 330 may be formed by using a method that may be utilized by a person skilled in the art.

The printed circuit board according to an example may include a first solder resist layer 411 and a second solder resist layer 412 respectively disposed above and below the interconnection portion 100. The first solder resist layer 411 may be disposed on the uppermost insulating layer among the second insulating layers 112, and the second solder resist layer 412 may be disposed on the lowermost insulating layer among the second insulating layers 112.

The first solder resist layer 411 and the second solder resist layer 412 may be disposed on the outermost portions of the printed circuit board, respectively, to protect the printed circuit board from the outside. The first solder resist layer 411 and the second solder resist layer 412 may use a known solder resist, and the first solder resist layer 411 and the second solder resist layer 412 may each include a thermosetting resin and an inorganic filler dispersed in the thermosetting resin, but may not include glass fibers. The insulating resin may be a photosensitive insulating resin, and the filler may be an inorganic filler and/or an organic filler, but the present disclosure is not limited thereto, and other polymer materials may be used as necessary. When a photosensitive insulating resin is used as the solder resist layer, it may be advantageous in forming a fine opening, but the present disclosure is not limited thereto, and the solder resist layer include a non-photosensitive insulating resin, and a fine opening may be formed using a UV laser.

The first solder resist layer 411 may cover at least a portion of the fine via 330. In addition, the metal post 420 may penetrate through a portion of the first solder resist layer 411 and may have a structure protruding from the first solder resist layer 411. The fact that the metal post 420 protrudes beyond the first solder resist layer 411 may mean that an upper surface of the metal post 420 may be located higher than an upper surface of the first solder resist layer 411.

The first solder resist layer 411 may expose at least a portion of the micro-via 330 through the first opening, and the first opening may be filled with the metal post 420. Here, a width of a lower portion of the metal post 420 in a region in which the metal post 420 and the micro-via 330 are in contact with each other may be formed to be smaller than the width of the micro-via 330. Meanwhile, a width of the first opening formed in the first solder resist layer 411 may also have various widths, like the width of the second opening described below, the width of the metal post 420 may be formed wider than the width of the micro-via 330.

The second solder resist layer 412 may have a second opening, and at least a portion of the second pad 142 may be exposed by the second opening. That a portion of the second pad 142 may be exposed by the second opening may mean that the second solder resist layer 412 covers the second pad 142, but the second solder resist layer 412 does not cover the second pad 142 in the region in which the second opening is formed. In other words, it may mean that not only the second pad 142 is exposed to the outside of the printed circuit board, but also the second solder resist layer 412 does not cover a portion of the second pad 142, so that a portion of the second pad 142 may be connected to another component.

Meanwhile, in FIG. 3, the second opening of the second solder resist layer 412 is illustrated as exposing a portion of an upper surface of the second pad 142, but the second solder resist layer 412, the second opening, and the second pad are not limited to being aligned in a solder mask defined (SMD) form and may be aligned in a non-solder mask defined (NSMD) form, and thus the relationship between the second pad 142 and the second solder resist layer 412 is not limited to that illustrated in the drawing. In the case of being aligned in the NSMD form, the width of the second opening of the second solder resist layer 412 may be formed wider than the width of the second pad 142, the upper surface of the second pad 142 may be exposed by the second solder resist layer 412, and the side surface of the second pad 142 may also be exposed by the second solder resist layer 412.

The printed circuit board according to an example may further include a metal post 420 disposed on at least a portion of the micro-via 330. The metal post 420 may be disposed on the micro-via 330 and may penetrate through at least a portion of the first solder resist layer 411. The metal post 420 may include a metal material. As the metal material, copper (Cu), aluminum (Al), silver (Ag), tin (Sn), gold (Au), lead (Pb), titanium (Ti), or alloys thereof may be used. The metal material may preferably include copper (Cu), but the present disclosure is not limited thereto. The metal post 420 may be a region for mounting electronic components, chips, etc., and may have a protruding configuration to facilitate connection when electronic components, chips, etc. are mounted in the micro-via 330. The metal post 420 may perform various functions depending on the design of the micro-via 330. The metal post 420 may electrically transmit and receive signals with the interconnection layer 120.

In a case in which the micro-via 330 requires a high-density micro pitch for mounting semiconductor chips, etc., not only a gap between the micro-vias 330 but also the gap between the metal posts 420 may be narrowed. As the metal post 420 is disposed on the micro-via 330, even if a micro pitch semiconductor chip is mounted, the possibility of a short circuit of a connecting member disposed between the semiconductor chip and the metal post 420 may be reduced, and the defect that the semiconductor chip escapes may be reduced. In addition, as the metal post 420 is disposed on the micro-via 330, adhesion may be secured through the metal post 420 compared to a structure in which a connecting member is directly disposed on the micro-via 330, and thus, the reliability of the printed circuit board may be improved.

The metal post 420 may be formed by, but is not limited to, one of the SAP, MSAP, TT, or Subtractive method, and may be formed by using a method that may be utilized by a person skilled in the art.

The printed circuit board according to an example may further include a surface treatment layer disposed on at least a portion of the metal post 420. The surface treatment layer may include one metal among nickel (Ni), palladium (Pd), and gold (Au), and these metal layers may be implemented in plural. For example, the surface treatment layer may be at least a portion of electroless nickel electroless palladium immersion gold (ENEPIG) structure and may be at least a portion of electroless nickel immersion structure (ENIG). The surface treatment layer is not limited thereto and may include an organic solder passivation (OSP) structure including an organic substance. The surface treatment layer may improve the adhesion and signal transmission between the metal post 420 and the connecting member. In FIG. 3, the surface treatment layer is illustrated as including one layer, but the present disclosure is not limited thereto, and the surface treatment layer may be implemented as a plurality of metal layers as described above.

The surface treatment layer may cover at least a portion of the metal post 420. In FIG. 3, the surface treatment layer is illustrated as covering the upper surface of the metal post 420, but without being limited thereto, the surface treatment layer may be disposed to further cover the exposed side surface of the metal post 420.

The printed circuit board according to an example may further include the electronic component 200 and an adhesive layer 210. The electronic component 200 may be an IC in which hundreds to millions of elements are integrated in one chip. For example, the electronic component 200 may be a processor chip, such as a central processor (e.g., CPU), a graphics processor (e.g., GPU), a field programmable gate array (FPGA), a digital signal processor, an encryption processor, a microprocessor, a microcontroller, and specifically, an application processor (AP), but the present disclosure is not limited thereto, and may also be memories such as volatile memories (e.g., DRAM), non-volatile memories (e.g., ROM), flash memories, analog-to-digital converters, or logic, such as application-specific ICs (ASICs). The electronic component 200 may be a chip-type passive component, for example, a chip inductor or chip capacitor. Or, it may be a combination of an IC and a chip-type passive component, in which case a plurality of cavities may be formed.

The electronic component 200 may be disposed in a cavity penetrating through at least a portion of the second insulating layer 112 and buried by the first insulating material 310. The electronic component 200 may further include an adhesive layer 210 in order to be mounted in the cavity. The structure and mounting of the electronic component 200 may be formed using a structure and method that may be utilized by those skilled in the art.

The connection pad 201 may be disposed on the upper surface of the electronic component 200. The electronic component 200 may be connected to the interconnection portion 100 through the connection pad 201, and the upper surface on which the connection pad 201 is disposed may be an active surface. However, without being limited thereto, and the electronic component 200 may be capable of double-sided connection and may have a three-dimensional structure in some cases.

The printed circuit board according to the example is not limited to the configuration illustrated in FIG. 3, may further include other components, and some components thereof may be omitted in some cases. That is, the printed circuit board may include more components that may be utilized by those skilled in the art.

### Method for Manufacturing Printed Circuit Board

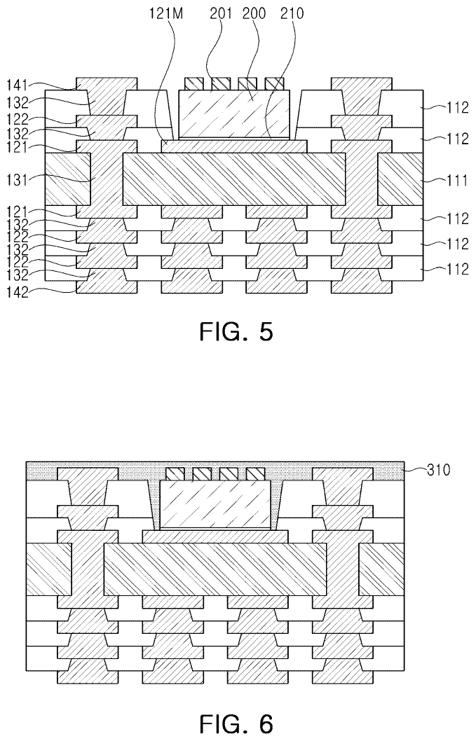

FIGS. 5 to 12 are cross-sectional views schematically illustrating a method for manufacturing a printed circuit board according to an example.

The method for manufacturing a printed circuit board according to an example may include an operation of preparing the interconnection portion 100 and the electronic component 200, an operation of burying the electronic component 200 with the first insulating material 310, an operation of etching a portion of the first insulating material 310, an operation of forming the second insulating material 320 with a micro-via hole processed on the first insulating material 310, an operation of forming the micro-via 330 on the second insulating material, an operation of forming solder resist layers 411 and 412 on the upper and lower sides of the interconnection portion 100, and an operation of forming the metal post 420.

Referring to FIG. 5, an operation of preparing the interconnection portion 100 and the electronic component 200 may be included. The interconnection portion 100 may include one or more insulating layers 110, one or more interconnection layers 120 respectively disposed on or within the one or more insulating layers 110, and one or more via layers 130 penetrating through the one or more insulating layers to connect the one or more interconnection layers. The operation of preparing the interconnection portion 100 may include an operation of forming the first interconnection layer 121 on the first insulating layer 111, may include an operation of forming the second insulating layer 112 on the first insulating layer 111 and forming the second interconnection layer 122, and may include an operation of forming one or more via layers 130 connecting the interconnection layers. In addition, an operation of forming the first pad 141 and the second pad 142 on the second insulating layer 112 disposed at the outermost portion may be included. Here, the operation of forming the insulating layer 110 and the interconnection layer 120 may be performed through a known build-up process.

Meanwhile, the method for manufacturing a printed circuit board according to an example may include an operation of forming a cavity penetrating through at least a portion of a second insulating layer 112 and mounting the electronic component 200 by attaching it with the adhesive layer 210.

Referring to FIG. 6, an operation of burying the electronic component 200 with the first insulating material 310 may be included. The first insulating material 310 may fill at least a portion of the cavity and bury the electronic component 200 The first insulating material 310 may be formed of a material including an insulating material but not including a fiber reinforcing material, such as glass cloth, for example, Ajinomoto build-up film (ABF). ABF may be provided in the form of resin coated copper (RCC), but the present disclosure is not limited thereto. If necessary, a photosensitive insulating material, such as photo imagable dielectric (PID) may be used.

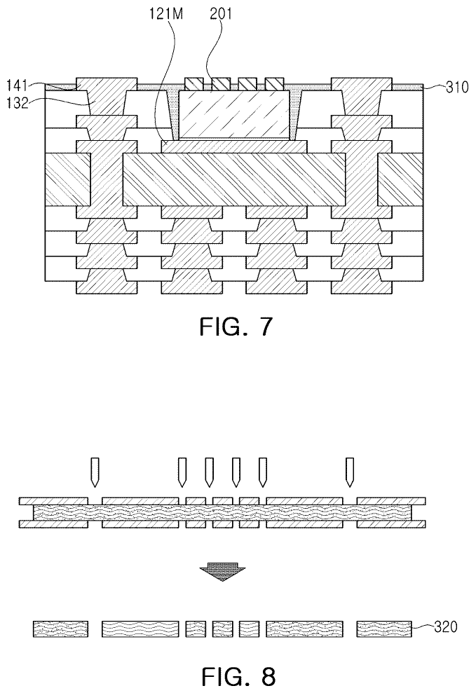

Referring to FIG. 7, an operation of etching a portion of the first insulating material 310 may be included. The first insulating material 310 may be partially etched through an etching process. Accordingly, the boundary surface of the first insulating material 310 and the second insulating material 320 may be located between the upper and lower surfaces of the first pad 141. Similarly, the boundary surface of the first insulating material 310 and the second insulating material 320 may be located between the upper and lower surfaces of the connection pad 201. As described below, the size of the micro-via hole may be reduced due to flow of a resin during the thermal compression process of the second insulating material 320 (prepreg). To prevent this, before the second insulating material 320 is stacked, the electronic first insulating component 200 may be embedded in the material 310 and then etched, thereby minimizing the volume that has to be filled with the second insulating material 320.

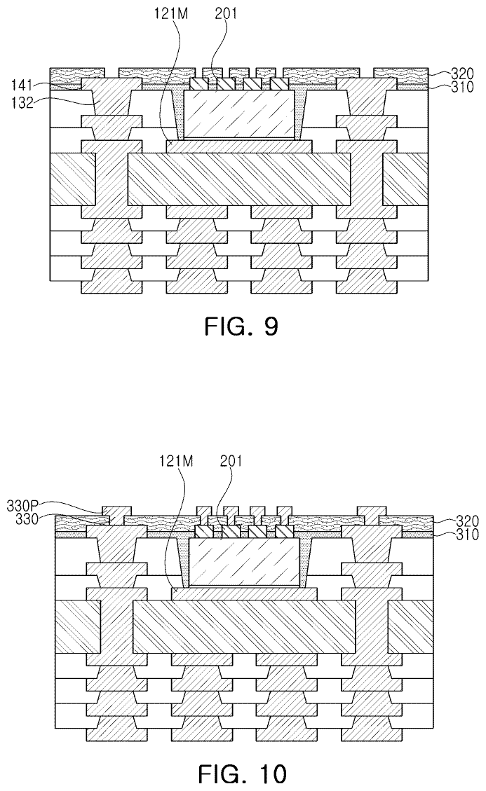

Referring to FIGS. 8 and 9, an operation of forming the second insulating material 320 with a micro-via hole processed on the first insulating material 310 may be included. Referring to FIG. 8, the micro-via hole may be formed by punching using a mold before the second insulating material 320 is stacked. The second insulating material 320 may be a prepreg including a fiber reinforcing material, such as glass cloth. Thereafter, as illustrated in FIG. 9, the second insulating material 320 with a micro-via hole processed is stacked on the first insulating material 310.

Referring to FIG. 10, an operation of forming the micro-via 330 on the second insulating material may be included. The micro-via 330 may penetrate through at least a portion of the second insulating material 320. The width (e.g., diameter) of the micro-via 330 may be smaller than that of at least one of the one or more via layers 130.

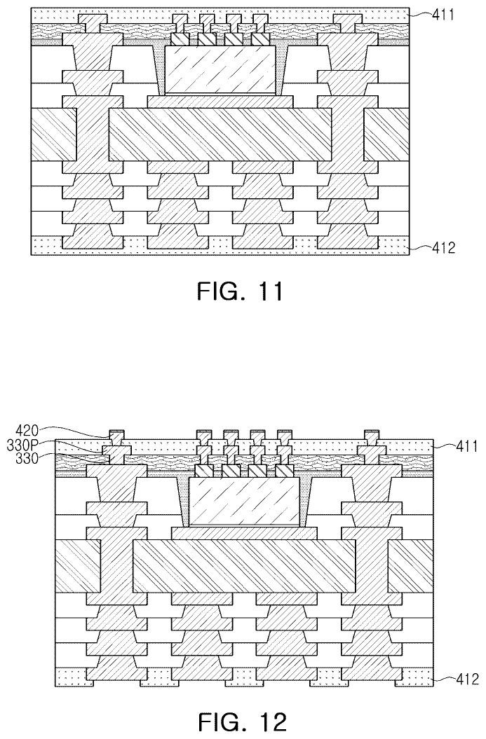

Referring to FIG. 11, an operation of forming the solder resist layer 411 and 412 on the upper and lower sides of the interconnection portion 100 may be included. Each solder resist layer may be formed simultaneously, but the present disclosure is not limited thereto. The method of forming the first solder resist layer 411 and the second solder resist layer 412 is not limited and may be a known method of forming a solder resist.

Referring to FIG. 12, an operation of forming the metal post 420 on the micro-via 330 may be included. In order to form the metal post 420, an opening may be formed in the first solder resist layer 411 to expose at least a portion of the micro-via 330. The method for forming the opening may be any known method for forming an opening, such as UV laser machining, or the like. After forming the metal post 420, a surface treatment layer may be formed on the upper surface of the metal post 420.

Meanwhile, the method for manufacturing a printed circuit board according to an example is not limited to the contents described above with reference to FIGS. 5 to 12 and may be appropriately modified and changed as needed.

As one of the effects of the present disclosure, the printed circuit board capable of implementing a metal post having a micro pitch in a printed circuit board for mounting electronic components and semiconductor chips, etc. may be provided.

As another of the effects of the present disclosure, the printed circuit board capable of improving reliability against warpage may be provided.

In the present disclosure, a cross-section may refer to a cross-sectional shape when an object is cut vertically, a cross-sectional shape when an object is cut vertically, or a cross-sectional shape when an object is viewed from a side view. In addition, “on a plane” may refer to a planar shape when an object is cut horizontally or a planar shape when an object is viewed from a top-view or bottom-view.

In this disclosure, the terms upper side, upper portion, upper surface, etc. are used for convenience to refer to a direction toward a surface on which electronic components may be mounted based on the cross-section of the drawings, and the terms lower side, lower portion, lower surface, etc. are used in the opposite direction. However, this is defined as a direction for convenience of description and the scope of the claims is not specifically limited by the description of such directions.

In the present disclosure, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” In addition, it may be understood that when an element is referred to with “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

In the present disclosure, determination may be made to include process errors, position deviations, errors during measurement, and the like that occur during a manufacturing process. For example, substantially being coplanar may include not only presence completely on the same plane, but also presence approximately on the same plane.

In the present disclosure, the same material may refer to not only the same material but also the same type of material. Accordingly, the composition of the materials may be substantially the same, but their specific composition ratios may be slightly different.

The expression “an exemplary embodiment or one example” used in the present disclosure does not refer to identical examples and is provided to stress different unique features between each of the examples. However, examples provided in the following description are not excluded from being associated with features of other examples and implemented thereafter. For example, even if matters described in a specific example are not described in a different example thereto, the matters may be understood as being related to the other example, unless otherwise mentioned in descriptions thereof.

The terms used herein are for the purpose of describing particular embodiments only and are not intended to limit the example embodiments. As used herein, the singular forms “a”, “an” and “the” are intended to include the plural forms as well, unless the context clearly indicates otherwise.

While example exemplary embodiments have been illustrated and described above, it will be apparent to those skilled in the art that modifications and variations could be made without departing from the scope of the present disclosure as defined by the appended claims.

What is claimed is:

1. A printed circuit board comprising:
an interconnection portion including one or more insulating layers, one or more interconnection layers, and one or more via layers and having a cavity penetrating through at least a portion of the one or more insulating layers;
an electronic component disposed in the cavity;
a first insulating material disposed in at least a portion of the cavity and burying at least a portion of the electronic component;
a second insulating material disposed on the first insulating material; and
a micro-via penetrating through at least a portion of the second insulating material and connected to the electronic component,
wherein the micro-via has a width smaller than at least one of the one or more via layers.

2. The printed circuit board of claim 1, wherein
the one or more insulating layers include a first insulating layer and a second insulating layer disposed on the first insulating layer, and
the one or more via layers include a first via penetrating through the first insulating layer and a second via penetrating through at least a portion of the second insulating layer.

3. The printed circuit board of claim 2, wherein the cavity penetrates throughs at least a portion of the second insulating layer.

4. The printed circuit board of claim 2, wherein the width of the micro-via is smaller than a width of the first via.

5. The printed circuit board of claim 2, wherein the width of the micro-via is smaller than a width of the second via.

6. The printed circuit board of claim 1, wherein the micro-via is spaced apart from one or more insulating layers.

7. The printed circuit board of claim 1, wherein the micro-via is spaced apart from the first insulating material.

8. The printed circuit board of claim 1, further comprising:
a solder resist layer disposed on an upper surface of the second insulating material; and
a metal post disposed on the micro-via and penetrating through at least a portion of the solder resist layer.

9. The printed circuit board of claim 1, wherein the second insulating material includes a reinforcing material.

10. The printed circuit board of claim 1, wherein the first insulating material does not include a fiber reinforcing material.

11. The printed circuit board of claim 1, wherein the second insulating material includes a material different from the first insulating material.

12. The printed circuit board of claim 11, wherein the second insulating material is more rigid than the first insulating material.

13. The printed circuit board of claim 1, wherein the electronic component includes a connection pad disposed in the first insulating material and the second insulating material, and
the micro-via extends from the connection pad.

14. A printed circuit board comprising:
an interconnection portion including one or more insulating layers and one or more interconnection layers and having a cavity penetrating through at least a portion of the one or more insulating layers;
a first insulating material disposed in at least portion of the cavity; and
a second insulating material disposed on the first insulating material and including a reinforcing material,
wherein an uppermost interconnection layer among the one or more interconnection layers includes a first pad, and an upper surface of the first pad is located within the second insulating material.

15. The printed circuit board of claim 14, wherein a boundary surface of the first insulating material and the second insulating material is located between the upper surface and a lower surface of the first pad.

16. The printed circuit board of claim 14, further comprising:
an electronic component disposed within the cavity and having a connection pad disposed on an upper surface thereof,
wherein an upper surface of the connection pad is located within the second insulating material.

17. The printed circuit board of claim 16, wherein a boundary surface of the first insulating material and the second insulating material is located between the upper surface of the connection pad and a lower surface of the connection pad.

18. The printed circuit board of claim 14, wherein the one or more insulating layers include a first insulating layer and a second insulating layer disposed on the first insulating layer, and
the one or more interconnection layers include a first interconnection layer disposed on the first insulating layer and a second interconnection layer disposed within the second insulating layer.

19. The printed circuit board of claim 18, wherein
the cavity penetrates through at least a portion of the second insulating layer.

20. The printed circuit board of claim 14, wherein the second insulating material is more rigid than the first insulating material.
